(19) United States
(12) Patent Application Publication
(10) Pub. No.: US 2023/0403799 A1
(43) Pub. Date: Dec. 14, 2023

(54) METHOD FOR FIXING ELECTRONIC COMPONENT PIN

(71) Applicant: FranklinWH Energy Storage Inc., SAN JOSE, CA (US)

(72) Inventors: Ye WEI, Shenzhen (CN); Daqing WANG, Shenzhen (CN)

(21) Appl. No.: 18/350,435

(22) Filed: Jul. 11, 2023

Related U.S. Application Data
(63) Continuation of application No. PCT/CN2022/097990, filed on Jun. 10, 2022.

(51) Int. Cl. H05K 3/34; H05K 13/04

(52) U.S. Cl. CPC H05K 3/34; H05K 13/04

(57) ABSTRACT

A method for fixing an electronic component pin is provided, and relates to the technical field of printed circuit board assembly (PCBA), for improving the soldering effect of the electronic component in being soldered. The method includes performing bending treatment on a pin of an electronic component; performing stress relieving forming to the pin after being subjected to the bending treatment; placing the electronic component after being subjected to the stress relieving forming in a height-controlling support jig, where the distance between the electronic component and a circuit board is defined by the height-controlling support jig; mounting the height-controlling support jig, in which the electronic component is placed, in a corresponding position of the electronic component on the circuit board; and soldering the electronic component onto the circuit board.

### CROSS-REFERENCE TO RELATED APPLICATION

This application is a continuation application of International Patent Application No. PCT/CN2022/097990, filed on Jun. 10, 2022, the content of which is incorporated herein by reference in its entirety.

### FIELD

The present application relates to the technical field of printed circuit board assembly (PCBA), and more particularly, to a method for fixing an electronic component pin.

### BACKGROUND

IGBT (Insulated Gate Bipolar Transistor) refers to an insulated gate bipolar type transistor.

MOSFET (Metal-Oxide-Semiconductor Field-Effect Transistor) refers to a metal-oxide semiconductor field-effect transistor.

In the conventional method for fixing a pin of an electronic component to a circuit board, the electronic component such as an IGBT or an MOSFET is first empirically mounted on the circuit board, and since the distance between the electronic component and the circuit board cannot be controlled in the process of mounting, it can only cut the extra pin portion after the soldering is finished. However, the distance between the electronic component and the circuit board may cause the electronic component to be pressed and damaged accordingly, in addition, in the process of soldering, the solder filling degree of via holes in the circuit board cannot be confirmed, and there is a risk of insufficient tin or excessive tin, which may cause a potential quality hazard to the circuit board. Therefore, the conventional method for fixing pins to the circuit board has an issue of poor pin soldering effect.

### SUMMARY

A method for fixing an electronic component pin is provided according to the present application, to improve the soldering effect of the electronic component in being soldered.

A method for fixing an electronic component pin, applied to fixing pins of an IGBT or MOSFET, includes as follows.

A bending treatment is performed on a pin of an electronic component.

A stress relieving forming is performed on the pin after being subjected to the bending treatment.

The electronic component after being subjected to the stress relieving forming is placed in a height-controlling support jig, where a distance between the electronic component and a circuit board is defined by the height-controlling support jig.

The height-controlling support jig, in which the electronic component is placed, is mounted in a corresponding position of the electronic component on the circuit board.

The electronic component is soldered on the circuit board.

Further, a bending angle for the bending treatment of the pin is 90°±3°.

Further, a distance between a bending position for the bending treatment of the pin and a body of the electronic component is greater than or equal to 2.5 mm.

Further, the stress relieving forming is performed on the pin after being subjected to the bending treatment by a forming processing device.

Further, the performing stress relieving forming to the pin after being subjected to the bending treatment includes processing the pin after being subjected to the bending treatment into a hook shape.

Further, the performing stress relieving forming to the pin after being subjected to the bending treatment includes processing the pin after being subjected to the bending treatment into an S-shape.

Further, after the electronic component is soldered on the circuit board, a distance between a top plane surface of a body of the electronic component and the circuit board ranges from 7.80 mm to 8.20 mm.

Further, the height-controlling support jig includes a bottom plate, a cover plate and a fastening screw; the cover plate is provided with a plurality of recesses, each of the plurality of recesses corresponds to one module, and the body of the electronic component is placed in the recess.

Further, the number of the recesses formed in the cover plate is determined according to deformation degrees of the bottom plate and the cover plate when the bottom plate and the cover plate are pressed.

Further, the height-controlling support jig is a two-module jig or a four-module jig, and two or four electronic components after being subjected to the stress relieving forming are placed in the height-controlling support jig.

According to the method for fixing an electronic component pin provided in the present application, the bending treatment is performed on the pin of the electronic component, a stress relieving forming is performed on the pin after being subjected to the bending treatment, thereby the pin stress of the electronic component is released, and the electronic component after being subjected to the stress relieving forming is placed on the height-controlling support jig, the distance between the electronic component and the circuit board is defined by the height-controlling support jig, the height-controlling support jig, on which the electronic component is placed, is placed in a corresponding position of the electronic component on the circuit board, the electronic component is fixed in the corresponding position of the electronic component on the circuit board by the height-controlling support jig, and the electronic component is soldered on the circuit board by the soldering technology. By performing the bending treatment and the stress relieving forming treatment on the pin of the electronic component, the damage to the pin due to stress caused when the pin is pressed is eliminated, the electronic component is prevented from being deformed, the filling effect of the solder in the soldering is ensured, the soldering effect of the electronic component is effectively improved, and the effect of circuit board conduction caused by excessive tin is avoided. The automatic soldering of pins is adopted, which, compared with the manual soldering, can effectively control the filling rates of the solder in via holes of the circuit board, and soldering is performed on all of the via holes at the same time, thereby, the efficiency of soldering is higher.

### BRIEF DESCRIPTION OF DRAWINGS

In order to more clearly illustrate the technical solutions of embodiments of the present application, the drawings to be used in the description of the embodiments of the present application are described briefly hereinafter. Apparently, the drawings in the description hereinafter only illustrate some embodiments of the present application. For the person of ordinary skill in the art, other drawings can be obtained from these drawings without making creative efforts.

FIG. 1 is a flowchart of a method for fixing an electronic component pin in an embodiment of the present application;

FIG. 2 is a schematic diagram showing the structure of an electronic component in an embodiment of the present application; and

FIG. 3 is a diagram showing an example of the structure of a height-controlling support jig in an embodiment of the present application.

### DETAILED DESCRIPTION

Technical solutions in embodiments of the present application are clearly and completely described in conjunction with drawings in the embodiments of the present application. Apparently, the embodiments described are only some embodiments in the present application rather than all embodiments. Based on the embodiments in the present application, all other embodiments obtained by the person skilled in the art without creative efforts are within the scope of the present application.

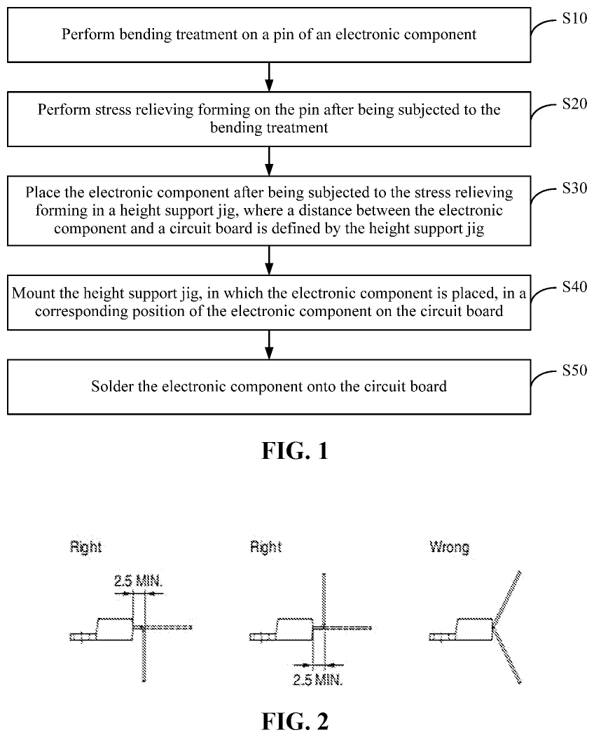

In an embodiment, as shown in FIG. 1, it is provided a method for fixing an electronic component pin, applied to fixing pins of an IGBT or MOSFET, the method includes: S10, S20, S30, S40 and S50.

In the S10, bending treatment is performed on a pin of an electronic component.

Specifically, an electronic component is an electronic element and a small-sized circuit module, and is a general term of electronic components such as capacitance and transistor. A bending point is set on the pin, the bending point is used as a bending position, the pin of the electronic component is subjected to a bending treatment, and after the pin is bent at a preset bending angle, the electronic component after being subjected to the bending treatment is obtained.

In this embodiment, the electronic component is specifically an insulated gate bipolar transistor (IGBT) or a metal-oxide-semiconductor field-effect transistor (MOSFET, which is a kind of field-effect transistor that can be widely applied in analog circuits and digital circuits).

An IGBT is a semiconductor device composed of a bipolar junction transistor (BJT) and an MOSFET.

The bending angle can be set according to the practical application scenario. In this embodiment, the pin of the electronic component is bent at 90 degrees, and the deviated value is 90°±3°.

As an optional embodiment, for two electronic components, while pins thereof are bent by force and are then pressed downwards, a slice analysis is further performed on the pins, and the analysis shows that the electronic components are not damaged due to stress.

In the S20, a stress relieving forming is performed on the pin after being subjected to the bending treatment.

Specifically, after the bending treatment is performed on the pin, a stress relieving forming is performed on the pin after being subjected to the bending treatment.

The steps in performing the stress relieving forming are as follows.

The pin is processed by a forming processing device, and the pin is processed into a particular shape for releasing stress in the pin. In this embodiment, the stress of the pin refers to the stress generated in the electronic component after the electronic component is pressed.

The particular shape is specifically an S-shape or a hook shape.

In the S30, the electronic component after being subjected to the stress relieving forming is placed in a height-controlling support jig, and the distance between the electronic component and the circuit board is defined by the height-controlling support jig.

Specifically, the height-controlling support jig includes a recess for placing an electronic component, the electronic component after being subjected to the stress relieving forming is placed in the height-controlling support jig, and the distance between the electronic component and the circuit board is adjusted by the height-controlling support jig.

Here, the distance between the electronic component and the circuit board refers to the height from a top plane surface of the electronic component to the circuit board.

In the S40, the height-controlling support jig, in which the electronic component is placed, is mounted in a corresponding position of the electronic component on the circuit board.

Specifically, the height-controlling support jig is mounted in a corresponding position of the electronic component on the circuit board, the pin of the electronic component placed in the height-controlling support jig passes through a via hole of the circuit board, the height of the electronic component is controlled by the height-controlling support jig, and the position in which the electronic component is mounted on the circuit board is limited by the height-controlling support jig so as to achieve the effects of position limiting and height limiting.

In the S50, the electronic component is soldered on the circuit board.

Specifically, the electronic component is soldered on the circuit board, and since before being soldered, the pins of the electronic component have been processed to allow the pins to release the stresses, and an automatic soldering technique is adopted to perform soldering of all the components, thereby improving the soldering efficiency of the electronic components.

As an exemplary embodiment, the electronic components are soldered on the circuit board by the wave soldering technology, and through the wave soldering, soldering to the pins of the electronic components can be performed automatically, thus, the issues of missing soldering, excessive tin and insufficient tin are avoided, and the phenomena of short circuit of the circuit board caused by the soldering issues are reduced.

In the wave soldering technique, flow is sprayed through an electric pump or an electromagnetic pump into a solder wave crest required by a design so that the circuit board pre-mounted with electronic components passes the solder wave crest, thereby realizing the connection between the circuit board and the pins of the electronic components.

Compared with the manual soldering, the wave soldering technology can effectively guarantee the solder filling rate of all the via holes via which the electronic components are mounted on the circuit board, and can effectively avoid the issue of tin bead generation, and avoid the potential quality hazard of the circuit board. The soldering time of manual soldering is relatively long, and it is known from experiment data that the soldering time of the wave soldering can be about 40 seconds less than the soldering time of the manual soldering. The flux residue in the wave soldering process is less, which has a certain beneficial effect on the quality of the circuit board.

Further, after the electronic component is soldered on the circuit board, a processing semi-finished product is obtained, and the processing semi-finished product is taken out of the height-controlling support jig to be subjected to a solder joint detection and height detection. Specifically, a measurement jig is employed to be retained into a corresponding electronic component to detect and determine whether a gap between the measurement jig and the electronic component is greater than 0.1 mm. If the gap does not exceed 0.1 mm, the processing semi-finished product is sprayed with a three-proof paint for protecting the circuit board.

As an optional embodiment, after the wave soldering, a support seat is mounted for the electronic component, and the support seat is capable of preventing the pins of the electronic component from being deformed due to receiving a force. When a vibration or heavily pressing occurs, the pins of the electronic component are prevented from being deformed by the support seat.

According to the method for fixing an electronic component pin provided in embodiments of the present application, the bending treatment is performed on the pin of the electronic component, a stress relieving forming is performed on the pin after being subjected to the bending treatment, thereby the pin stress of the electronic component is released, and the electronic component after being subjected to the stress relieving forming is placed on the height-controlling support jig, the distance between the electronic component and the circuit board is defined by the height-controlling support jig, the height-controlling support jig, on which the electronic component is placed, is placed in a corresponding position of the electronic component on the circuit board, the electronic component is fixed in the corresponding position of the electronic component on the circuit board by the height-controlling support jig, and the electronic component is soldered on the circuit board by the soldering technology. By performing the bending treatment and the stress relieving forming treatment on the pin of the electronic component, the damage to the pin due to stress caused when the pin is pressed is reduced, the electronic component is prevented from being deformed in a certain degree, the filling effect of the solder in the soldering is ensured, the soldering effect of the electronic component is effectively improved, and the effect of circuit board conduction caused by excessive tin is avoided. Further, the wave soldering is adopted, which, compared with the manual soldering, can effectively control the filling rates of the solder in the via holes of the circuit board, and soldering can be performed on all of the via holes at the same time, thereby, the efficiency of soldering is improved.

In another embodiment, the finished product PCBA after being soldered by the wave soldering is assembled in a power conversion module, the height of the electronic component in a state of being mounted in the PCBA is 7.8 mm, the height of the power conversion module in a state of being assembled is 8 mm, and the PCBA is assembled in the power conversion module with a certain gap retained.

Through tests, it is proved that the gap between the electronic component and the power conversion module facilitates heat dissipation of the electronic component. When the power conversion module has been worked for two hours under the load of 45 KW, no obvious abnormality is found in the temperature of the surface of the electronic component, and no faults happened in the working process.

In addition, in order to reduce the temperature of the electronic component in working, silicone grease is roller-coated on the surface of the electronic component to ensure that the area of contact of the silicone grease with the electronic component can cover the pins of the electronic component. Roller-coating the silicone grease facilitates reduction of the surface temperature of the electronic component in working and prevents short circuit of the electronic component caused by overly high temperature.

Further, a bending angle for the bending treatment of the pin is 90°±3°.

It is to be noted that the bending angle of the electronic component is 90°, the deviation value is ±3°, and the pin is bent in a direction towards the top plane surface of the electronic component at an angle of 90°±3°, or bent in a direction towards a bottom plane surface of the electronic component at an angle of 90°±3°.

In this embodiment, the pin of the electronic component is bent at the angle of 90°±3°, so that it is easier to mount the electronic component onto the circuit board. In addition, the pin of the electronic component is bent, thus in the process of subsequent soldering, when a vibration or a heavy pressing occurs, the electronic component can withstand a certain degree of pressing force, thereby preventing deformation of the pin and deterioration of the soldering effect caused accordingly.

Further, a distance between a bending position for the bending treatment of the pin and a body of the electronic component is greater than or equal to 2.5 mm.

The bending position is set, and the bending position is used as a turning point for the pin bending, and there is certain distance between the bending position and the body of the electronic component. As an exemplary embodiment, the distance between the bending position and the body of the electronic component is greater than or equal to 2.5 mm.

As shown in FIG. 2, when the electronic component is placed horizontally, the bending position is 2.5 mm from the body of the electronic component. With the bending position as an axis, the pin is bent downward of the electronic component at an angle of 90°±3° or the pin is bent upward of the electronic component at an angle of 90°±3°.

The bending position is required to retain a distance of 2.5 mm or more from the body of the electronic component. After the electronic component is mounted on the circuit board, a gap is retained between the bottom plane surface of the electronic component and the circuit board, which facilitates heat dissipation of the electronic component in working.

It was tested that after all the pins of the electronic component are bent with the distance of 2.5 mm from the body of the electronic component retained, no abnormality occurred during subsequent encapsulation of the finished product PCBA.

According to an experimental comparison, three electronic components were observed, and on the basis of the distance between the bending position and the body, three groups of embodiments, 1.5 mm*1, 2 mm*1, and 2.5 mm*1, were set, and it was tested that when the distance between the bending position and the body is greater than 2.5 mm, no abnormality was found in the circuit board after being encapsulated. Further, the stress relieving forming is performed on the pin after being subjected to the bending treatment through a forming processing device.

The pin after being subjected to the bending treatment is treated by a forming processing device to allow the pin to release stress in the process, thereby avoiding damage to the pin of the electronic component caused by the stress.

The stress relieving forming specifically refers to performing an irregular shaping treatment on the pin to form the pin into a shape capable of releasing the stress.

Further, the performing the stress relieving forming on the pin after being subjected to the bending treatment includes processing the pin after being subjected to the bending treatment into a hook shape.

Further, the performing the stress relieving forming on the pin after being subjected to the bending treatment includes processing the pin after being subjected to the bending treatment into an S-shape.

The stress relieving forming includes processing the pin after being subjected to the bending treatment into an S-shape or a hook shape. By processing the pin into a shape capable of releasing the stress through the new technology for stress relieving forming, it avoids a situation in which the electronic component is damaged due to being subjected to the stress in the process of being soldered.

Further, after the electronic component is soldered on the circuit board, the distance between the top plane surface of the body of the electronic component and the circuit board ranges from 7.80 mm to 8.20 mm.

The distance of the top plane surface of the electronic component from the circuit board is controlled by the height-controlling support jig, and after the electronic component is soldered on the circuit board, the distance between the top plane surface of the body of the electronic component and the circuit board ranges from 7.80 mm to 8.20 mm.

If the distance between the top plane surface of the electronic component and the circuit board is too large, it is apt to increase the stress applied to the electronic component when the electronic component is pressed, which may cause damage to the electronic component. If the distance between the top plane surface of the electronic component and the circuit board is too small, in practical use, there is a risk that the heat dissipation is poor, which may cause damage to the circuit.

In this embodiment, it has been verified that by controlling the distance between the top plane surface of the electronic component and the circuit board to be between 7.80 mm and 8.20 mm, the stress issue caused by too long or too short of the pins of the electronic component can be addressed, and in addition, the issue of poor solder filling effect caused by too long or too short of the pins can be avoided, thereby effectively ensuring the quality of the circuit board.

Preferably, the distance between the body of the electronic component and the circuit board is set to range from 7.95 mm to 8.15 mm, and after the electronic component is mounted to the circuit board, the stress to which the electronic component is subjected can be further reduced.

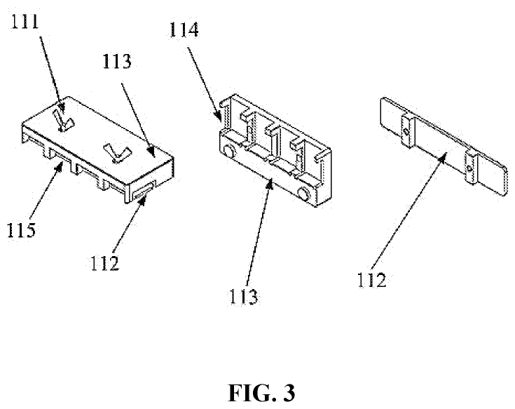

Further, as shown in FIG. 3, the height-controlling support jig includes a bottom plate 112, a cover plate 113 and a fastening screw 111. The cover plate 113 is provided with multiple recesses 114, each of the recesses 114 corresponds to a module, and the body of the electronic component is placed in the recess 114.

The height-controlling support jig includes the bottom plate 112, the cover plate 113 and the fastening screw 111 for fastening the bottom plate 112 and the cover plate 113. The cover plate 113 is provided therein with the multiple recesses 114 for accommodating the electronic components, and corresponding openings 115 are provided outside of the recesses, for placing pins of the electronic components.

The electronic components are placed in the recesses of the cover plate 113, the bottom plate 112 is used to cover on the recesses, and the bottom plate 112 and the cover plate 113 are fixed by the fastening screw 111, to thereby fixing the electronic components.

The height-controlling support jig is mounted on the circuit board, and a head side of the recess is configured for passing the pin of the electronic component through a via hole of the circuit board.

After the soldering of the electronic component pins at the opening 115 end of the recesses 114 finishes, the bottom plate 112 is separated from the cover plate 113, and then the electronic component pins at the other end are soldered.

In this embodiment, multiple recesses 114 are provided in the height-controlling support jig, and multiple electronic components can be soldered at one time, thereby improving efficiency.

Further, the number of the recesses formed in the cover plate 113 is determined in accordance with the deformation degrees of the bottom plate 112 and the cover plate 113 when the bottom plate 112 and the cover plate 113 are pressed.

Further, the height-controlling support jig is a two-module jig or a four-module jig, and two or four electronic components after being subjected to the stress relieving forming are placed in the height-controlling support jig.

Specifically, the number of the recesses formed in the cover plate is determined in accordance with the deformation degrees of the bottom plate and the cover plate when the bottom plate and the cover plate are pressed and deformed. Specifically, one module corresponds to one recess.

As an exemplary embodiment, the height-controlling support jig is a two-module jig or a four-module jig. The height-controlling support jig having two modules or four modules can be used to process two or four electronic components at one time, and the height-controlling support jig having two modules and the height-controlling support jig having four modules can more accurately control the distance between the circuit board and the electronic components, to allow the error to be controlled within the range of ±0.1 mm.

Specifically, the support seat, for supporting the electronic components, of the height-controlling support jig has a small thickness and is susceptible to deformation, for a four-module jig, the electronic components have little adverse effect on the deformation of the support seat, so that the height control effect of the four-module jig can be the most accurate.

On this basis, the height-controlling support jig configured as the two-module jig or the four-module jig can have the most accurate effect on the height control.

In an embodiment, as shown in FIG. 2, an electronic component is provided, which is an insulated gate bipolar transistor (IGBT) or a metal-oxide-semiconductor filed-effect transistor (MOSFET).

The distance of the bending position of the pin from the body of the electronic component is greater than or equal to 2.5 mm.

The bending angle of the pin of the electronic component is 90°±3°.

The bending direction of the pin of the electronic component is to be bent downward or bent upward.

The pin of the electronic component is in a hook shape or an S-shape.

It should be noted that after the pin of the electronic component is subjected to the bending treatment, the pin of the electronic component is subjected to the stress relieving forming, and is processed into the hook shape or the S-shape.

In this embodiment, by performing the bending treatment and the stress relieving forming on the pin of the electronic component, it is ensured that when the electronic component is pressed, the pin of the electronic component will not be deformed, thus ensuring the soldering effect of soldering the electronic component onto the circuit board.

In an embodiment, as shown in FIG. 3, a height-controlling support jig for electronic components is provided, which includes a bottom plate 112, a cover plate 113, and a fastening screw 111. The cover plate 113 is provided with multiple recesses 114, each of the recesses 114 corresponds to one module, and the body of the electronic component is placed in the recess 114.

Further, the height-controlling support jig is a two-module jig or a four-module jig, and two or four electronic components are placed in the height-controlling support jig.

Further, the height-controlling support jig is made of a material such as glass fiber, aluminum alloy or synthetic stone.

The height-controlling support jig is configured to control the distance between the top plane surface of the electronic component and the circuit board, and set the distance between the top plane surface of the electronic component and the circuit board to range from 7.80 mm to 8.20 mm to play the role of height control.

Specifically, the electronic component after being subjected to the bending treatment and the stress relieving forming is mounted to the height-controlling support jig, the height-controlling support jig, on which the electronic component is mounted, is mounted to the circuit board, and the distance between the top plane surface of the electronic component and the circuit board is controlled by the height-controlling support jig, thereby the effect of the soldering can be effectively ensured.

Specifically, the electronic component is an IGBT or an MOSFET. In this embodiment, the height-controlling support jig is configured to place the electronic components so as to control the distance between the top plane surface of the electronic component and the circuit board, thereby the soldering effect of soldering the electronic component to the circuit board can be ensured.

It should be understood that the sequence numbers of the steps in the above-described embodiment do not imply the sequence of execution, and the sequence of execution of the processes should be determined by their functions and intrinsic logic, and should not constitute any limitation on the implementation of the embodiments of the present application.

The meaning of “first” and “second” in the above modules/units is only to distinguish different modules/units rather than defining which module/unit has higher priority or having other defining meanings. In addition, the terms “including” and “having” as well as any variation of them are intended to cover non-exclusive inclusion. For example, a process, method, system, product or equipment that contains a series of steps or modules need not be limited to those steps or modules that are clearly listed, but can include other steps or modules that are not clearly listed or are inherent in the process, method, product or equipment. The division of modules in this application is only a logical division, there may be other ways of division when to implement in practical applications.

It will be clear to a person skilled in the art that, for the convenience and brevity of description, the division of the above-mentioned functional units and modules are described only for example. In practical application, the above-mentioned functions can be allocated to different functional units and modules according to requirements for performing, that is, the inside structure of the device can be divided into different functional units or modules, so as to perform all or part of the functions described above.

The above-described embodiments are only intended to illustrate the technical solution of the present application rather than limiting it. Although the present application has been described in detail with reference to the afore-mentioned embodiments, it will be appreciated by the person of ordinary skill in the art that the technical solutions set forth in the afore mentioned embodiments may still be modified, or equivalent substitutions may still be made for some of the technical features therein. These modifications or substitutions do not make essence of the corresponding technical solutions depart from the spirit and scope of the technical solutions of the embodiments of the present application, and are intended to be encompassed within the scope of protection of the present application.

What is claimed is:

1. A method for fixing an electronic component pin, applied to fixing pins of an insulated gate bipolar transistor (IGBT) or a metal-oxide-semiconductor field-effect transistor (MOSFET), comprising:
performing bending treatment on a pin of an electronic component;
performing stress relieving forming on the pin after being subjected to the bending treatment;
placing the electronic component after being subjected to the stress relieving forming in a height-controlling support jig, wherein a distance between the electronic component and a circuit board is defined by the height-controlling support jig;
mounting the height-controlling support jig, in which the electronic component is placed, in a corresponding position of the electronic component on the circuit board; and
soldering the electronic component onto the circuit board.

2. The method for fixing the electronic component pin according to claim 1, wherein a bending angle for the bending treatment of the pin is 90°±3°.

3. The method for fixing the electronic component pin according to claim 2, wherein a distance between a bending position for the bending treatment of the pin and a body of the electronic component is greater than or equal to 2.5 mm.

4. The method for fixing the electronic component pin according to claim 1, wherein the stress relieving forming is performed on the pin after being subjected to the bending treatment by a forming processing device.

5. The method for fixing the electronic component pin according to claim 1, wherein the performing stress relieving forming to the pin after being subjected to the bending treatment comprises processing the pin after being subjected to the bending treatment into a hook shape.

6. The method for fixing the electronic component pin according to claim 1, wherein the performing stress relieving forming to the pin after being subjected to the bending treatment comprises processing the pin after being subjected to the bending treatment into an S-shape.

7. The method for fixing the electronic component pin according to claim 1, wherein after the electronic component is soldered on the circuit board, a distance between a top plane surface of a body of the electronic component and the circuit board ranges from 7.80 mm to 8.20 mm.

8. The method for fixing the electronic component pin according to claim 1, wherein the height-controlling support jig comprises a bottom plate, a cover plate and a fastening screw; the cover plate is provided with a plurality of recesses, each of the plurality of recesses corresponds to one module, and a body of the electronic component is placed in the recess.

9. The method for fixing the electronic component pin according to claim 8, wherein a number of the recesses provided in the cover plate is determined according to deformation degrees of the bottom plate and the cover plate when the bottom plate and the cover plate are pressed.

10. The method for fixing the electronic component pin according to claim 8, wherein the height-controlling support jig is a two-module jig or a four-module jig, and two or four electronic components after being subjected to the stress relieving forming are placed in the two-module jig or the four-module jig.

11. The method for fixing the electronic component pin according to claim 4, wherein the performing stress relieving forming to the pin after being subjected to the bending treatment comprises processing the pin after being subjected to the bending treatment into a hook shape.

12. The method for fixing the electronic component pin according to claim 4, wherein the performing stress relieving forming to the pin after being subjected to the bending treatment comprises processing the pin after being subjected to the bending treatment into an S-shape.

13. The method for fixing the electronic component pin according to claim 9, wherein the height-controlling support jig is a two-module jig or a four-module jig, and two or four electronic components after being subjected to the stress relieving forming are placed in the two-module jig or the four-module jig.
